(19) United States
(12) Patent Application Publication
(10) Pub. No.: US 2026/0190402 A1
(43) Pub. Date: Jul. 2, 2026

(54) SEMICONDUCTOR DEVICE INCLUDING SEED LAYER AND METHOD FOR MANUFACTURING THE SAME

(71) Applicant: TAIWAN SEMICONDUCTOR MANUFACTURING COMPANY, LTD., Hsinchu (TW)

(72) Inventors: Ting-Hsiang CHANG, Hsinchu (TW); Shu Ling LIAO, Hsinchu (TW); Yu-Ru LIN, Hsinchu (TW); Sung-En LIN, Hsinchu (TW); Tze-Liang LEE, Hsinchu (TW)

(73) Assignee: TAIWAN SEMICONDUCTOR MANUFACTURING COMPANY, LTD., Hsinchu (TW)

(21) Appl. No.: 19/002,260

(22) Filed: Dec. 26, 2024

(51) Int. Cl. H10D 62/10; H01L 21/02; H10D 30/00; H10D 30/01; H10D 84/01; H10D 84/83

(52) U.S. Cl. CPC H10D 62/116; H10D 30/0196; H10D 30/508; H10D 84/0151; H10D 84/832; H10P 14/274; H10D 30/509; H10P 14/24

(57) ABSTRACT

A method for manufacturing a semiconductor device includes: forming a stack structure on a substrate, the stack structure including sacrificial layer portions and channel layer portions which are alternately stacked; forming a trench that penetrates the stack structure and that terminates at an upper surface of the substrate; forming an insulator layer to cover the substrate and the stack structure; forming a seeding layer on the insulator layer; forming a protecting layer on the seeding layer; removing the protecting layer, an upper portion and an interconnecting portion of the seeding layer, and an upper portion and an interconnecting portion of the insulator layer; and forming a source/drain portion on a lower portion of the insulator layer and a lower portion of the seeding layer.

### BACKGROUND

With continuous development of semiconductor technology, functionality and electrical performance of transistors (e.g., p-channel metal-oxide-semiconductor (PMOS) transistors or n-channel metal-oxide-semiconductor (NMOS) transistors) are being continuously improved. However, improvement in the functionality and the electrical performance of the transistors may be hindered by some process issues, resulting in formation of defects in the transistors. The semiconductor industry is devoted to solving these process issues.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2A to 15 are schematic views illustrating some intermediate stages of the method as depicted in FIGS. 1A and 1B in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

A semiconductor device including a plurality of nanosheet transistors (e.g., nanosheet field-effect transistors (FETs)) has wide applications due to superior device performance. A nanosheet FET structure is a type of a gate-all-around FET (GAAFET) structure. In a nanosheet transistor, an insulator layer is disposed between a silicon substrate and a source/drain portion, and may be referred to as a flexible bottom insulator (FBI). The disposition of the insulator layer is conducive to lowering leakage current and capacitance (between the source/drain portion and adjacent ones of metal gates) in the nanosheet transistor, and to further improving device performance thereof. However, some issues may occur with the disposition of the insulator layer, and may adversely affect growth of the source/drain portion. For example, when the source/drain portion is formed on the insulator layer, voids may be formed in a bottom part of the source/drain portion, which may adversely affect the device performance (e.g., a direct current (DC) performance) of the semiconductor device.

In order to solve the abovementioned issue (formation of the voids), a seeding layer is utilized and is formed between the insulator layer and the source/drain portion. The seeding layer is made of, for example, but not limited to, silicon, silicon germanium, or silicon phosphide, and is formed by a suitable deposition process (e.g., chemical vapor deposition (CVD)), followed by conducting a partial etching back process using a suitable etching technique. By having the seeding layer, the voids may be eliminated in the bottom part of the source/drain portion. However, a crystallinity of the bottom part of the source/drain portion may decrease, which may result in an increase in electrical resistance of the source/drain portion and a decrease in carrier mobility of the nanosheet transistor, thereby adversely affecting the device performance of the semiconductor device.

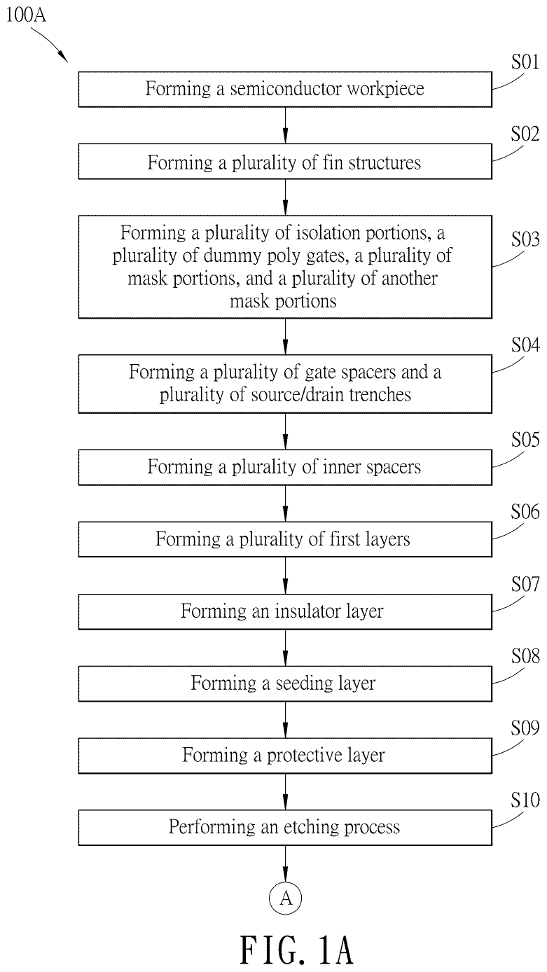

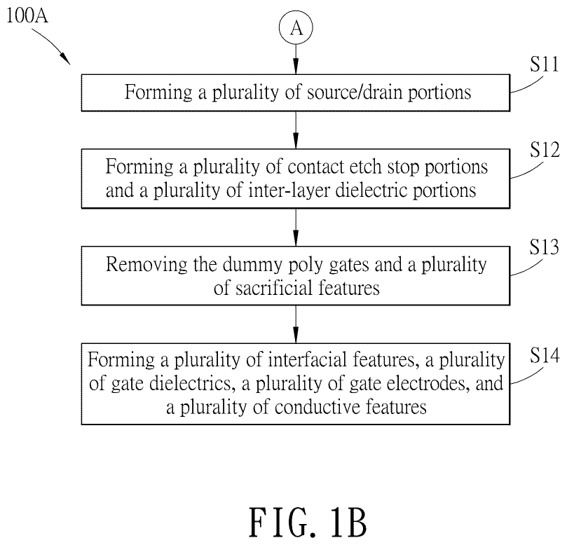

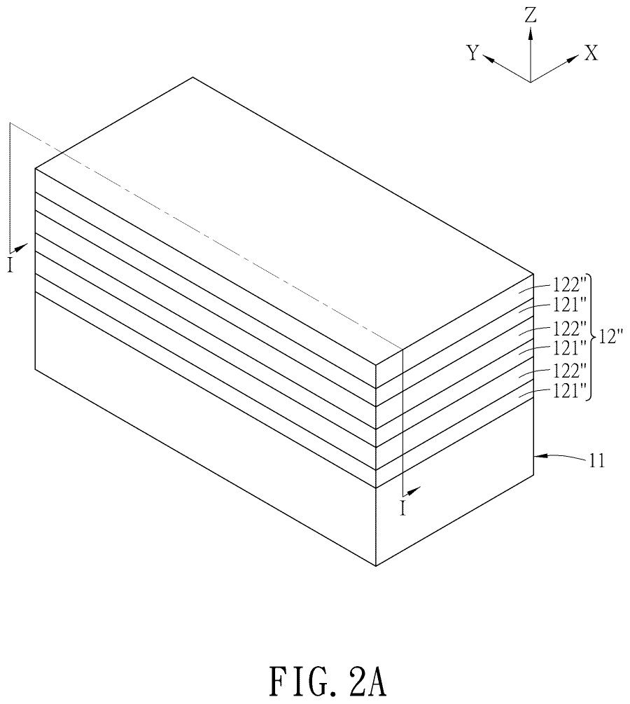

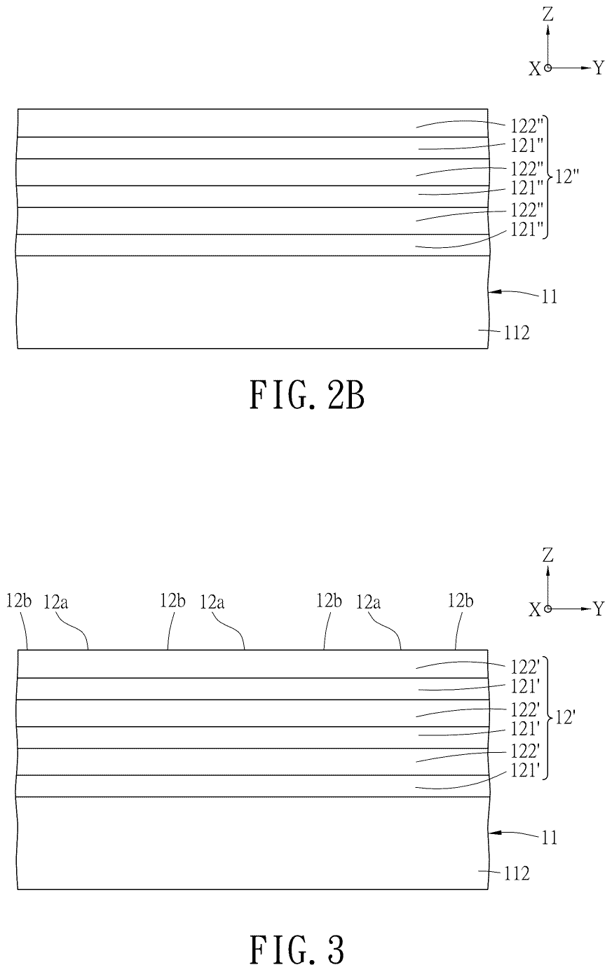

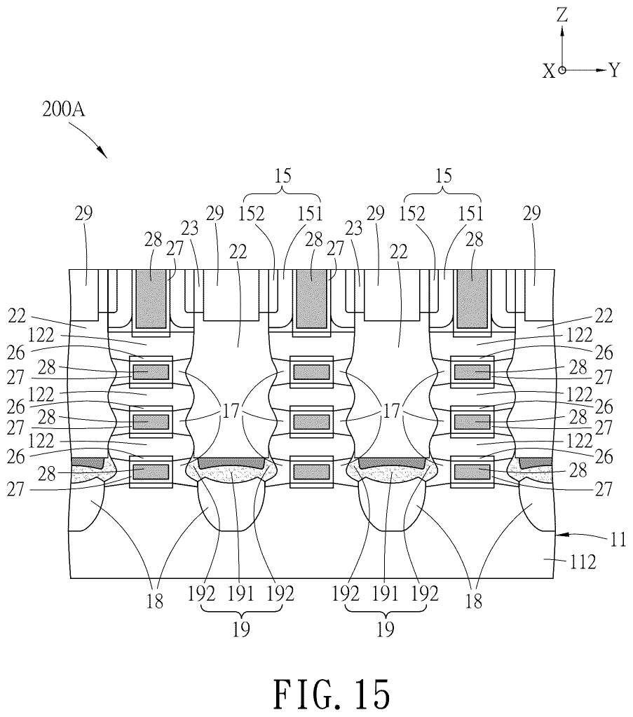

The present disclosure is directed to a semiconductor device and a method for manufacturing the same. FIGS. 1A and 1B are flow diagrams illustrating a method 100A for manufacturing a semiconductor device 200A shown in FIG. 15 in accordance with some embodiments. FIGS. 2A to 14 illustrate schematic views of some intermediate stages of the method 100A. Some portions may be omitted in FIGS. 2A to 14 for the sake of brevity. Additional steps can be provided before, after or during the method 100A, and some of the steps described herein may be replaced by other steps or be eliminated.

Referring to FIG. 1A and the example illustrated in FIGS. 2A and 2B, the method 100A begins at step S01, where a semiconductor workpiece is formed. FIG. 2B illustrates a cross-sectional view taken along line I-I of FIG. 2A. The semiconductor workpiece includes a semiconductor substrate 11 and a nanosheet stack 12″.

The semiconductor substrate 11 may include, for example, but not limited to, an elemental semiconductor or a compound semiconductor. In some embodiments, the elemental semiconductor includes a single species of atoms, such as silicon or germanium in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 11 may include a multilayer compound semiconductor structure. In some embodiments, the semiconductor substrate 11 may be a semiconductor on insulator (SOI) (e.g., silicon germanium on insulator (SGOI)). The SOI substrate may be doped with a p-type dopant, for example, but not limited to, boron, aluminum, or gallium. Other suitable p-type dopant materials are within the contemplated scope of the present disclosure. Alternatively, the SOI substrate may be doped with an n-type dopant, for example, but not limited to, nitrogen, phosphorous, or arsenic. Other suitable n-type dopant materials are within the contemplated scope of the present disclosure.

The nanosheet stack 12″ is disposed on the semiconductor substrate 11 in a Z direction normal to the semiconductor substrate 11. The nanosheet stack 12″ includes a plurality of sacrificial layers 121″ and a plurality of channel layers 122″ disposed to alternate with the sacrificial layers 121″ in the Z direction. In some embodiments, the nanosheet stack 12″ is a stack of semiconductor materials. In some embodiments, the sacrificial layers 121″ are made of a first semiconductor material, and the channel layers 122″ are made of a second semiconductor material that is different from the first semiconductor material, so that each layer of the channel layers 122″ has an etching selectivity (or an etching rate) different from that of each layer of the sacrificial layers 121″. In some embodiments, the first semiconductor material may be silicon germanium, and the second semiconductor material may be silicon, so that each layer of the sacrificial layers 121″ has an etching selectivity (or an etching rate) greater than that of each layer of the channel layers 122″. In some embodiments, the nanosheet stack 12″ may be formed on the semiconductor substrate 11 by a suitable deposition process (for example, but not limited to, CVD, atomic layer deposition (ALD), etc.), or a suitable epitaxial growth process (for example, but not limited to, molecular beam epitaxy (MBE), selective epitaxial growth (SEG) process, etc.). Other suitable processes for forming the nanosheet stack 12″ are within the contemplated scope of the present disclosure.

Referring to FIG. 1A and the example illustrated in FIG. 3, the method 100A then proceeds to step S02, where the semiconductor workpiece is patterned to form a plurality of fin structures 12′. One of the fin structures 12′ is shown in FIG. 3. Step S02 may be performed by a photolithography process, which includes an etching process. The etching process may be, for example, but not limited to, an anisotropic etching process. After this step, the semiconductor substrate 11 is formed into a lower portion (not shown) and a plurality of fin portions 112 that are disposed on the lower portion and that are spaced apart from one another in an X direction transverse to the Z direction; the sacrificial layers 121″ are formed into a plurality of sacrificial layer portions 121′; and the channel layers 122″ are formed into a plurality of channel layer portions 122′. The fin structures 12′ extend in a Y direction that is transverse to the Z direction and the X direction, and that is parallel to the semiconductor substrate 11. The fin structures 12′ are spaced apart from one another by trenches (not shown) in the X direction. Each of the fin structures 12′ is disposed on a corresponding one of the fin portions 112 of the semiconductor substrate 11, and includes corresponding ones of the sacrificial layer portions 121′ and corresponding ones of the channel layer portions 122′ disposed to alternate with the corresponding ones of the sacrificial layer portions 121′ in the Z direction. In some embodiments, an upper surface of each of the fin structures 12′ may have a plurality of covered regions 12a and a plurality of exposed regions 12b that are alternated with one another in the Y direction.

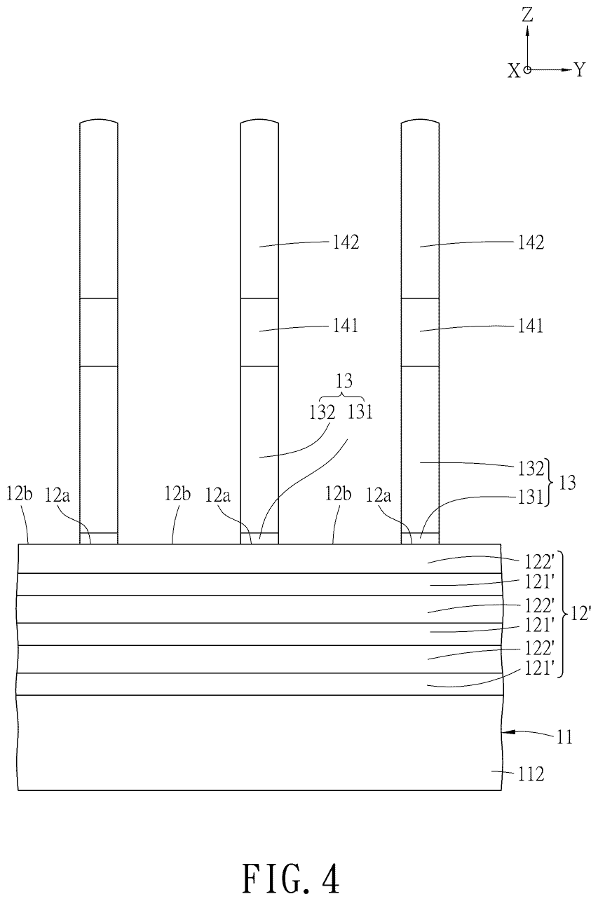

Referring to FIG. 1A and the example illustrated in FIG. 4, the method 100A then proceeds to step S03, where a plurality of isolation portions (not shown), a plurality of dummy poly gates 13, a plurality of mask portions 141, and a plurality of mask portions 142 are formed on the structure shown in FIG. 3. The dummy poly gates 13, the mask portions 141, and the mask portions 142 are formed on the isolation portions and over the fin structures 12′, and are spaced apart from each other in the Y direction. Each of the dummy poly gates 13 includes a dummy gate dielectric 131 (i.e., a plurality of the dummy gate dielectrics 131 are formed after step S03) and a dummy gate electrode 132 (i.e., a plurality of the dummy gate electrodes 132 are formed after step S03). Step S03 includes sub-steps (i) to (v).

In sub-step (i), the isolation portions are formed on the lower portion of the semiconductor substrate 11. Each pair of the isolation portions is located at two opposite sides of a corresponding one of the fin portions 112 of the semiconductor substrate 11 so as to separate and isolate the fin structures 12′ from each other. The two opposite sides of the corresponding one of the fin portions 112 are opposite to each other in the X direction. In some embodiments, the isolation portions may be made of an oxide-based material (e.g., silicon oxide), a nitride-based material (e.g., silicon nitride), or a combination thereof. Other suitable materials for forming the isolation portions are within the contemplated scope of the present disclosure. In some embodiments, the isolation portions may be formed by a suitable deposition process, for example, but not limited to, CVD or physical vapor deposition (PVD) so as to form an isolation material layer on the structure shown in FIG. 3, followed by conducting an etching back process to remove a portion of the isolation material layer. Other suitable processes for forming the isolation portions are within the contemplated scope of the present disclosure. In some embodiments, each of the isolation portions may be a portion of a shallow trench isolation (STI), a deep trench isolation (DTI), or other suitable isolation structures.

In sub-step (ii), a first dummy layer (not shown) for forming the dummy gate dielectrics 131 is conformally formed on the structure obtained after sub-step (i) by a suitable deposition process, for example, but not limited to, CVD, ALD, or PVD. In some embodiments, the first dummy layer may be made of an oxide-based material (e.g., silicon oxide). Other suitable materials for forming the first dummy layer are within the contemplated scope of the present disclosure.

In sub-step (iii), a second dummy layer (not shown) for forming the dummy gate electrodes 132 is formed on the structure obtained after sub-step (ii), followed by conducting a planarization process to remove an excess portion of the second dummy layer. In some embodiments, the second dummy layer may include polysilicon. Other suitable materials for forming the second dummy layer are within the contemplated scope of the present disclosure. In some embodiments, the second dummy layer may be formed by a suitable deposition process, for example, but not limited to, CVD, ALD, or PVD. In some embodiments, the planarization process may be a chemical mechanical polishing (CMP) or other suitable planarization processes.

In sub-step (iv), a mask material layer (not shown) for forming the mask portions 141 and a mask material layer (not shown) for forming the mask portions 142 are formed sequentially on the structure obtained after sub-step (iii). In some embodiments, the mask material layer for forming the mask portions 141 may include an oxide-based material (e.g., silicon oxide), and the mask material layer for forming the mask portions 142 may include a nitride-based material (e.g., silicon nitride). Other suitable materials for forming the mask material layers are within the contemplated scope of the present disclosure.

In sub-step (v), the structure obtained after sub-step (iv) is patterned by a photolithography process, which includes an etching process, thereby obtaining the dummy poly gates 13, the mask portions 141, and the mask portions 142.

The dummy gate dielectric 131 of each of the dummy poly gates 13 is disposed on a corresponding one of the covered regions 12a of each of the fin structures 12′. The dummy gate electrode 132 is disposed on the dummy gate dielectric 131. Each of the mask portions 141 is disposed on a corresponding one of the dummy poly gates 13. Each of the mask portions 142 is disposed on a corresponding one of the mask portions 141 opposite to a corresponding one of the dummy poly gates 13.

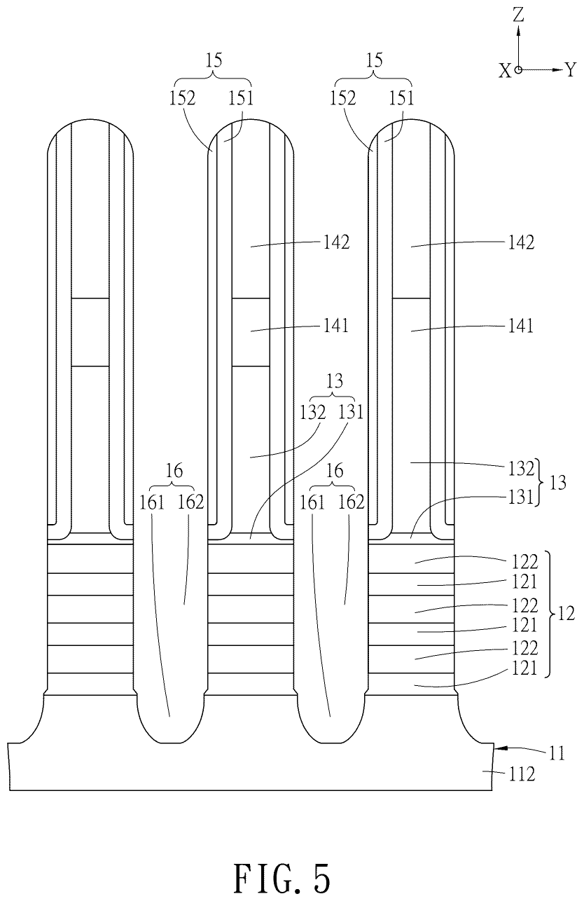

Referring to FIG. 1A and the example illustrated in FIG. 5, the method 100A then proceeds to step S04, where a plurality of gate spacers 15 are formed to laterally cover the dummy poly gates 13, followed by recessing the fin structures 12′ (see FIG. 4) to form a plurality of source/drain trenches 16. Step S04 includes sub-steps (i) and (ii).

In sub-step (i), at least one gate spacer material layer (not shown) for forming the gate spacers 15 is formed over the structure shown in FIG. 4. In some embodiments, the at least one gate spacer material layer may include, for example, but not limited to, silicon oxide, silicon nitride, silicon oxynitride, silicon carbonitride, silicon oxycarbonitride, or low-dielectric constant (k) materials. Other suitable materials for forming the at least one gate spacer material layer are within the contemplated scope of the present disclosure. In some embodiments, the at least one gate spacer material layer may be formed by a suitable deposition process, for example, but not limited to, CVD or ALD. Other suitable deposition processes for forming the at least one gate spacer material layer are within the contemplated scope of the present disclosure. In some embodiments, the at least one gate spacer material layer is formed to cover two opposite sides of each of the dummy poly gates 13, two opposite sides of each of the mask portions 141, two opposite sides and an upper surface of each of the mask portions 142, and the exposed regions 12b of the fin structures 12′ (see FIG. 4).

In sub-step (ii), two etching processes (e.g., anisotropic dry etching processes or other suitable etching processes) are sequentially performed on the structure obtained after sub-step (i) to remove portions of the at least one gate spacer material layer, which are respectively formed on the exposed regions 12b of the fin structures 12′ and the upper surface of each of the mask portions 142, followed by removing portions of the fin structures 12′ through the exposed regions 12b of the fin structures 12′ (see FIG. 4). After sub-step (ii), the gate spacers 15 and the source/drain trenches 16 are obtained. In some embodiments, when the at least one gate spacer material layer includes two of the gate spacer material layers, each of the gate spacers 15 includes an inner portion 151, which is one of remaining portions of one of the gate spacer material layers, and an outer portion 152, which is one of remaining portions of the other one of the gate spacer material layers. In some embodiments, each pair of the gate spacers 15 is respectively formed at two opposite sides of a corresponding one of the dummy poly gates 13, two opposite sides of a corresponding one of the mask portions 141, and two opposite sides of a corresponding one of the mask portions 142. In some embodiments, the source/drain trenches 16 are spaced apart from one another in the Y direction. After this step, the fin structures 12′ (see FIG. 4) are formed into a plurality of stack portions 12. Each of the stack portions 12 includes a plurality of sacrificial features 121 (formed from the sacrificial layer portions 121′ (see FIG. 4)) and a plurality of channel features 122 (formed from the channel layer portions 122′ (see FIG. 4)). In some embodiments, each of the source/drain trenches 16 includes a lower trench portion 161 and an upper trench portion 162 disposed above and in spatial communication with the lower trench portion 161.

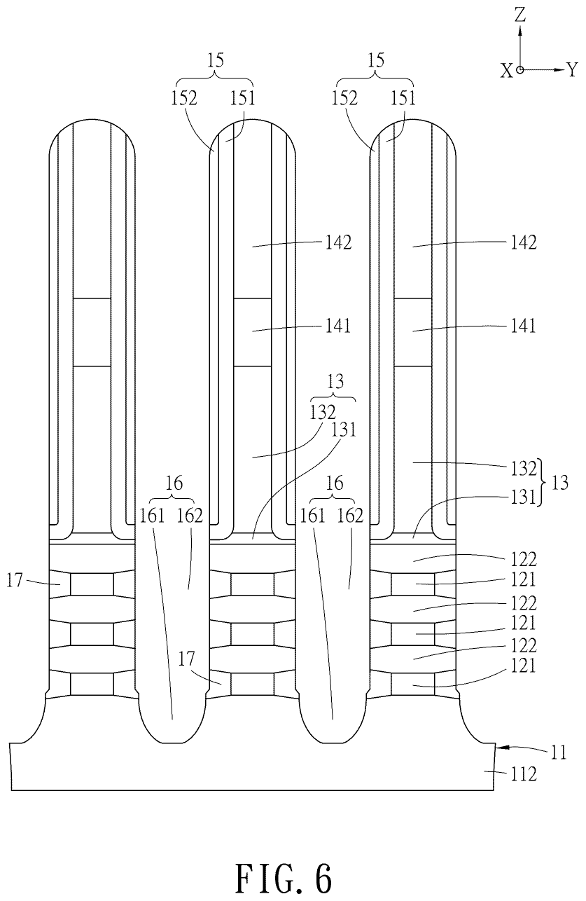

Referring to FIG. 1A and the example illustrated in FIG. 6, the method 100A then proceeds to step S05, where a plurality of inner spacers 17 are formed. Step S05 includes sub-steps (i) and (ii).

In sub-step (i), an isotropic etching process is performed on the structure shown in FIG. 5 to remove side portions of the sacrificial features 121 based on a relatively high etching selectivity of the sacrificial features 121 with respect to the channel features 122, so as to form a plurality of lateral recesses (not shown).

In sub-step (ii), an inner spacer material layer for forming the inner spacers 17 is formed on the structure obtained after sub-step (i) to fill the lateral recesses, followed by performing an etching process to remove an excess portion of the inner spacer material layer, thereby obtaining the inner spacers 17. In some embodiments, the inner spacer material layer may include, for example, but not limited to, silicon oxide, silicon nitride, silicon carbide, silicon oxycarbide, silicon oxynitride, silicon carbonitride, silicon oxycarbonitride, low-k materials, or combinations thereof. In some embodiments, the inner spacer material layer may be formed by a suitable deposition process, for example, but not limited to, CVD, ALD, or other suitable deposition processes. In some embodiments, the etching process may be a dry etching process, a wet etching process, or a combination thereof.

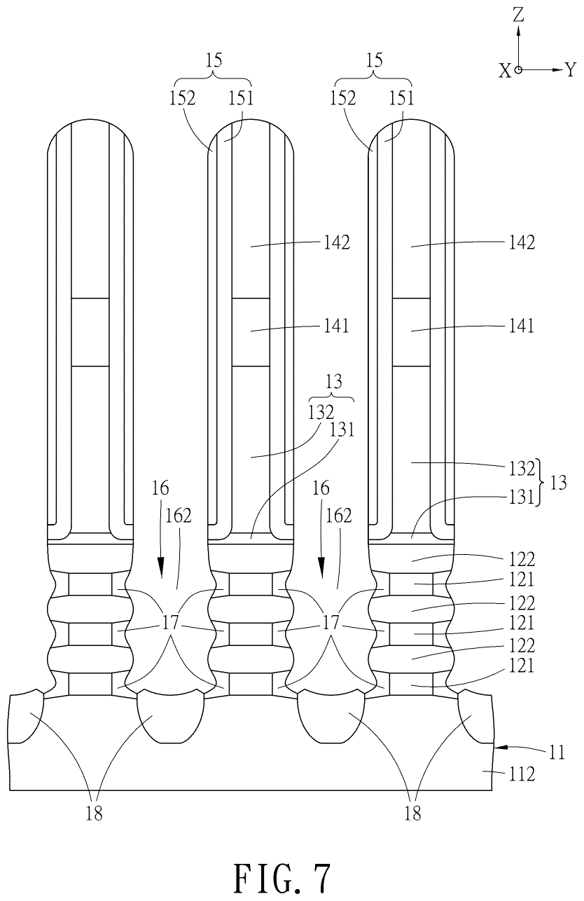

In some embodiments, after step S05 and before step S06, a plurality of clean processes (e.g., a wet clean process or other suitable clean processes) may be performed on the structure shown in FIG. 6, so that each of the inner spacers 17 is slightly and laterally recessed (see, for example, FIG. 7).

In some embodiments, after step S05, the channel features 122 may be slightly different in shape. For examples, an upper surface of each of uppermost ones of the channel features 122 is flat while an upper surface of each of remaining ones of the channel features 122 is curved.

Referring to FIG. 1A and the example illustrated in FIG. 7, the method 100A then proceeds to step S06, where a plurality of first layers 18 are formed in the lower trench portions 161 of the source/drain trenches 16 (see FIG. 6), respectively. In some embodiments, the first layers 18 may be made of, for example, but not limited to, silicon (e.g., undoped silicon). In some embodiments, the first layers 18 may be formed by a suitable epitaxial growth process, for example, but not limited to, the SEG process. In some embodiments, each of the first layers 18 may have a curved upper surface. In some embodiments, each of the first layers 18 may have two opposite side portions that protrude upwardly in the Z direction.

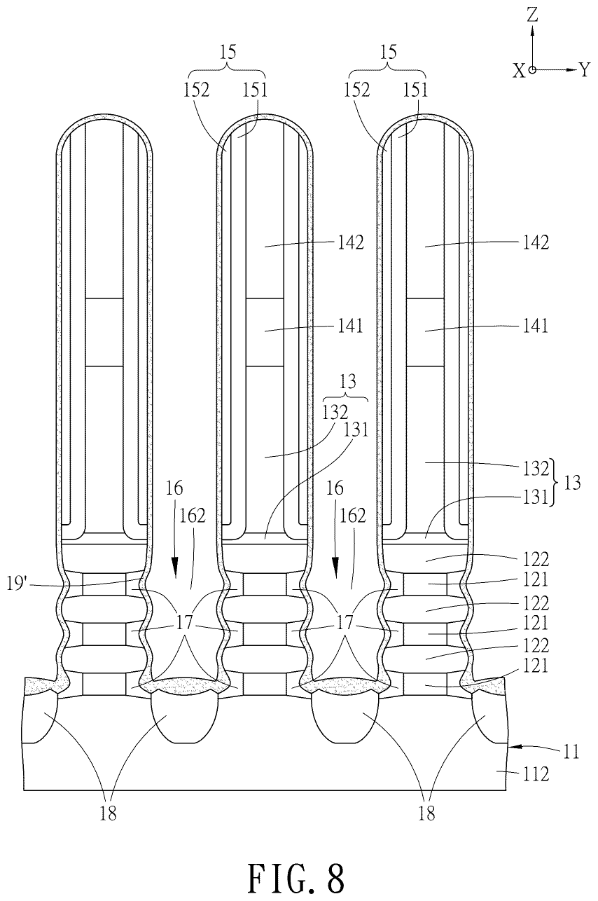

Referring to FIG. 1A and the example illustrated in FIG. 8, the method 100A then proceeds to step S07, where an insulator layer 19′ is formed on the structure shown in FIG. 7. In some embodiments, the insulator layer 19′ may be made of a dielectric material, for example, but not limited to, silicon nitride, silicon oxide, silicon oxynitride, or combinations thereof. Other suitable materials for forming the insulator layer 19′ are within the contemplated scope of the present disclosure. In some embodiments, the insulator layer 19′ may be formed by a suitable deposition process, for example, but not limited to, CVD or ALD. Other suitable deposition processes for forming the insulator layer 19′ are within the contemplated scope of the present disclosure. In some embodiments, the insulator layer 19′ may have a thickness ranging from about 3 nm to about 4 nm. In some embodiments, the insulator layer 19′ includes a plurality of upper portions, a plurality of lower portions and a plurality of interconnecting portions. Each of the upper portions of the insulator layer 19′ is disposed on an upper surface of each of a corresponding one pair of the gate spacers 15 and a corresponding one of the mask portions 142; each of the lower portions of the insulator layer 19′ is disposed on a corresponding one of the first layers 18; and each of the interconnecting portions of the insulator layer 19′ extends in the Z direction to interconnect a corresponding one of the upper portions of the insulator layer 19′ and a corresponding one of the lower portions of the insulator layer 19′, and is disposed on a side surface of a corresponding one of the gate spacers 15, side surfaces of corresponding ones of the channel features 122, and side surfaces of corresponding ones of the inner spacers 17. In some embodiments, a thickness of each of the lower portions of the insulator layer 19′ is greater than a thickness of each of the upper portions of the insulator layer 19′ and a thickness of each of the interconnecting portions of the insulator layer 19′. In some embodiments, the insulator layer 19′, the inner spacers 17 and the gate spacers 15 may be made of the same or different materials.

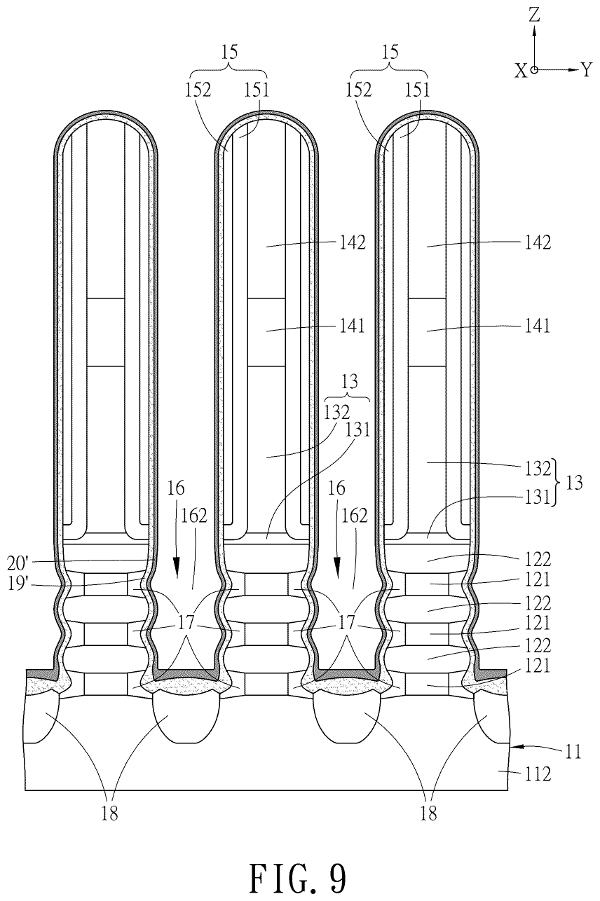

Referring to FIG. 1A and the example illustrated in FIG. 9, the method 100A then proceeds to step S08, where a seeding layer 20′ is formed on the structure shown in FIG. 8. In some embodiments, the seeding layer 20′ may be made of a semiconductor material, for example, but not limited to, amorphous silicon, silicon phosphide, silicon boron, or combinations thereof. Other suitable semiconductor materials for forming the seeding layer 20′ are within the contemplated scope of the present disclosure. In some embodiments, the semiconductor material for forming the seeding layer 20′ may be doped with a p-type dopant (e.g., boron, aluminum, or gallium) or an n-type dopant (e.g., nitrogen, phosphorous, or arsenic). In some embodiments, the seeding layer 20′ may have a density ranging from about 2.2 g/cm³ to about 2.3 g/cm³. In some embodiments, the seeding layer 20′ may have a thickness not greater than about 3 nm. In some embodiments, the seeding layer 20′ may be formed by a suitable deposition process, for example, but not limited to, plasma-enhanced CVD (PECVD). In some embodiments, the PECVD may be conducted using two plasma generators simultaneously, where each of the two plasma generators is a radio frequency (RF) plasma generator or a direct current (DC) plasma generator.

In some embodiments, the two plasma generators are the RF plasma generators, where one of the RF plasma generators is used for conducting the PECVD at a low frequency ranging from about 350 KHz to about 2 MHz, and the other one of the RF plasma generators is used for conducting the PECVD at a high frequency ranging from about 13 MHz to about 27 MHz. In some embodiments, a power of the RF plasma generator when the PECVD is conducted at the low frequency (ranging from about 350 KHz to about 2 MHz) is greater than about 0 watt (W) and is up to about 50 W. In some embodiments, a power of the RF plasma generator when the PECVD is conducted at the high frequency (ranging from about 13 MHz to about 27 MHz) ranges from about 60 W to about 300 W.

In some embodiments, the two plasma generators are the DC plasma generators, where a power of each of the DC plasma generators may be lower than about 100 W.

In some embodiments, one of the two plasma generators is the RF plasma generator and the other one of the two plasma generators is the DC plasma generator, where the RF plasma generator may be used for conducting the PECVD at the high frequency ranging from about 13 MHz to about 27 MHz and with the power ranging from about 60 W to about 300 W.

In some embodiments, the PECVD may be conducted at a pressure ranging from about 0.4 Torr (T) to about 3 T. If the pressure is lower than 0.4 T, formation of the seeding layer 20′ may be adversely affected. If the pressure is greater than 3 T, the desired density (i.e., ranging from about 2.2 g/cm³ to about 2.3 g/cm³) of the seeding layer 20′ may not be achieved.

In some embodiments, the seeding layer 20′ includes a plurality of upper portions, a plurality of lower portions and a plurality of interconnecting portions. Each of the upper portions of the seeding layer 20′ is disposed on a corresponding one of the upper portions of the insulator layer 19′; each of the lower portions of the seeding layer 20′ is disposed on a corresponding one of the lower portions of the insulator layer 19′; and each of the interconnecting portions of the seeding layer 20′ extends in the Z direction to interconnect a corresponding one of the upper portions of the seeding layer 20′ and a corresponding one of the lower portions of the seeding layer 20′, and is disposed on a side surface of a corresponding one of the interconnecting portions of the insulator layer 19′. In some embodiments, a thickness of each of the lower portions of the seeding layer 20′ is greater than a thickness of each of the upper portions of the seeding layer 20′ and a thickness of each of the interconnecting portions of the seeding layer 20′.

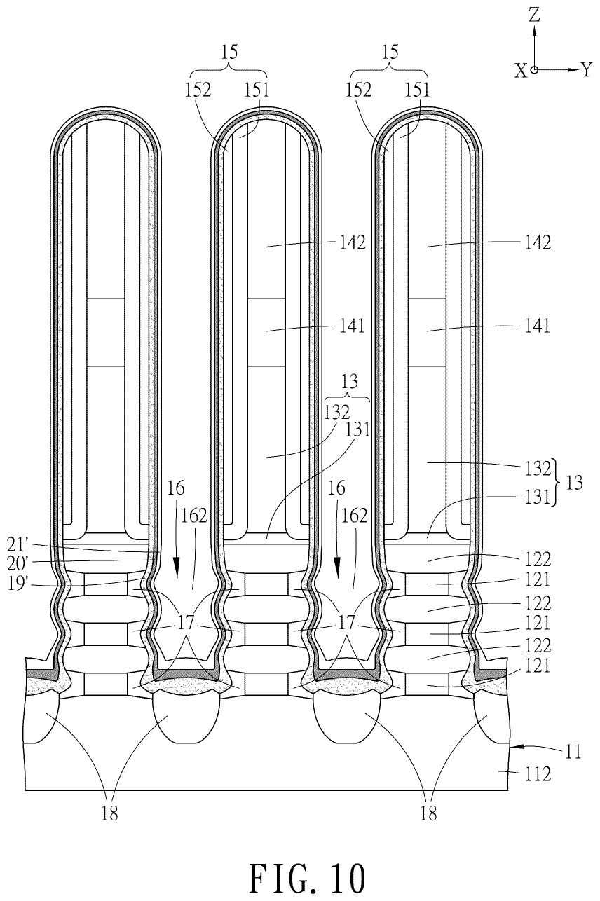

Referring to FIG. 1A and the example illustrated in FIG. 10, the method 100A then proceeds to step S09, where a protective layer 21′ is formed on the structure shown in FIG. 9. In some embodiments, the protective layer 21′ is made of a dielectric material layer, for example, but not limited to, silicon nitride, silicon oxide, silicon oxynitride, or combinations thereof. Other suitable materials for forming the protective layer 21′ are within the contemplated scope of the present disclosure. In some embodiments, the protective layer 21′ may be formed by a suitable deposition process, for example, but not limited to, CVD or ALD. Other suitable deposition processes for forming the protective layer 21′ are within the contemplated scope of the present disclosure. In some embodiments, the protective layer 21′ may have a thickness not greater than about 2 nm. In some embodiments, the protective layer 21′ includes a plurality of upper portions, a plurality of lower portions and a plurality of interconnecting portions. Each of the upper portions of the protective layer 21′ is disposed on a corresponding one of the upper portions of the seeding layer 20′; each of the lower portions of the protective layer 21′ is disposed on a corresponding one of the lower portions of the seeding layer 20′; and each of the interconnecting portions of the protective layer 21′ extends in the Z direction to interconnect a corresponding one of the upper portions of the protective layer 21′ and a corresponding one of the lower portions of the protective layer 21′, and is disposed on a side surface of a corresponding one of the interconnecting portions of the seeding layer 20′. In some embodiments, a thickness of each of the lower portions of the protective layer 21′ is greater than a thickness of each of the upper portions of the protective layer 21′ and a thickness of each of the interconnecting portions of the protective layer 21′. In some embodiments, the protective layer 21′ and the insulator layer 19′ may be made of the same material or different materials.

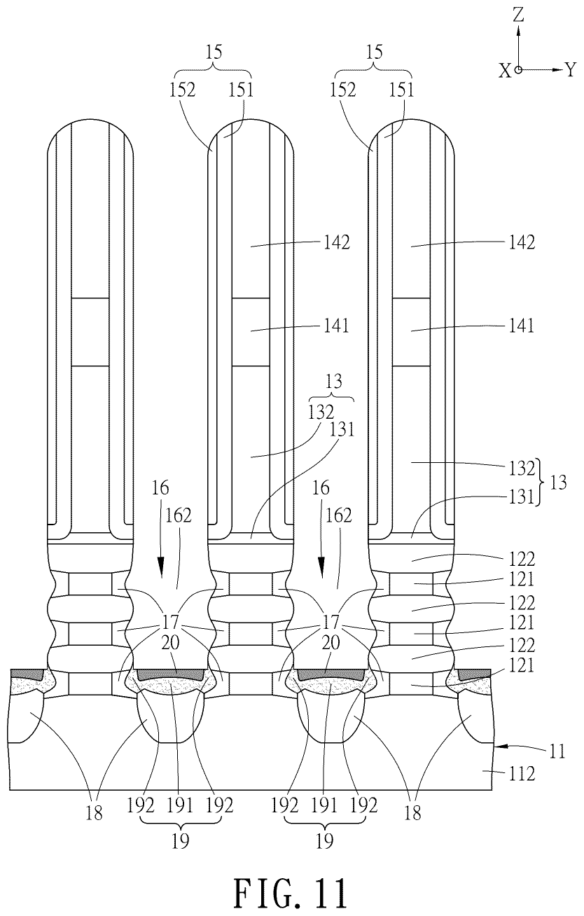

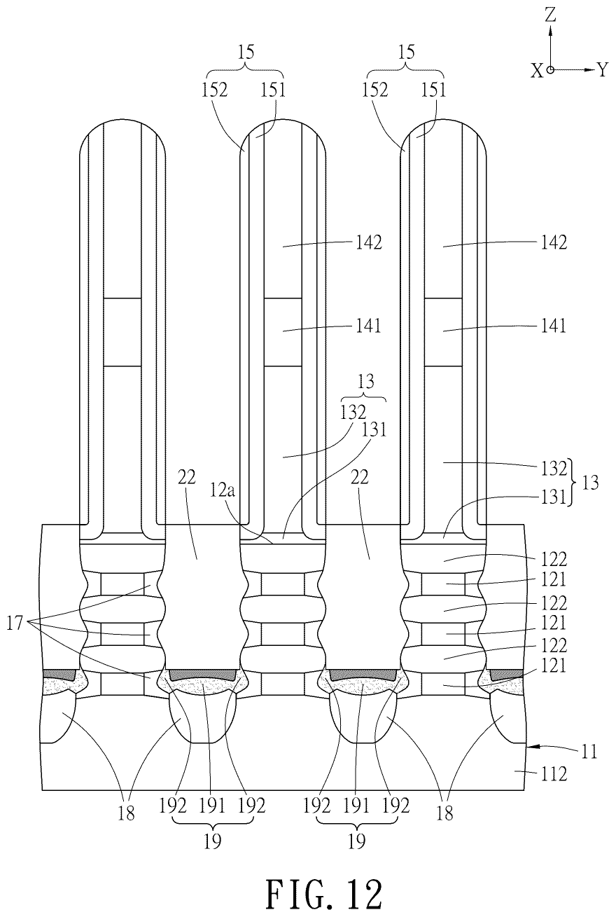

Referring to FIG. 1A and the example illustrated in FIG. 11, the method 100A then proceeds to step S10, where the upper and interconnecting portions of the protective layer 21′, the upper and interconnecting portions of the seeding layer 20′, and the upper and interconnecting portions of the insulator layer 19′ are removed until upper surfaces of the lower portions of the seeding layer 20′ are exposed. Step S10 may be performed by a suitable etching process, for example, but not limited to, a dry etching process, a wet etching process, or a combination thereof. In some embodiments, an etchant used in the dry etching process may include, for example, but not limited to, hydrogen fluoride, nitrogen trifluoride, or a combination thereof. In some embodiments, an etchant used in the wet etching process may include, for example, but not limited to, dilute hydrogen fluoride, standard clean 1 (SC-1) solution (including a combination of ammonium hydroxide, hydrogen peroxide, and deionized water), or a combination thereof. Other suitable etchants used in each of the dry etching process and the wet etching process are within the contemplated scope of the present disclosure. After this step, a plurality of insulators 19 (i.e., the lower portions of the insulator layer 19′) and a plurality of seed features 20 (i.e., the lower portions of the seeding layer 20′ which are protected by the protective layer 21′ during the etching process) are formed. In some embodiments, each of the seed features 20 may have a cross section of a rectangular shape or a trapezoid shape. Other geometrical shapes for the cross section of each of the seed features 20 are within the contemplated scope of the present disclosure. In some embodiments, each of the seed features 20 may have a flat upper surface. In some embodiments, each of the seed features 20 may have a curved lower surface. In some embodiments, a thickness of a center portion of each of the seed features 20 is less than that of each of two opposite side portions of the each of the seed features 20. In some embodiments, each of the two opposite side potions of the each of the seed features 20 may have a cross-section of a tooth shape. In some embodiments, each of the insulators 19 includes a main portion 191 and a side portion 192 extending upwardly from a periphery of the main portion 191, and each of the seed features 20 is disposed on the main portion 191 of a corresponding one of the insulators 19 and is surrounded by the side portion 192 of the corresponding one of the insulators 19. In some embodiments, a total thickness of each of the seed features 20 and the main portion 191 of a corresponding one of the insulators 19 in the upper trench portion 162 of a corresponding one of the source/drain trenches 16 may range from about 3 nm to about 6 nm. If the total thickness is lower than 3 nm, the semiconductor device 200A (see FIG. 15) may have a leakage current. If the total thickness is greater than 6 nm, a bottom part of each of a plurality of source/drain portions 22 (which will be described hereinafter with reference to, for example, FIG. 12) may have defects (e.g., voids) formed therein or a reduced crystallinity, which may adversely affect electrical resistance of the each of the source/drain portions 22, and may further reduce carrier mobility in the semiconductor device 200A, thereby adversely affecting device performance thereof. In some embodiments, a dielectric constant value (i.e., a k value) of the insulators 19 is greater than that of the inner spacers 17 and that of the gate spacers 15. In some embodiments, a density of the insulators 19 is greater than that of the inner spacers 17 and that of the gate spacers 15.

Referring to FIG. 1B and the example illustrated in FIG. 12, the method 100A then proceeds to step S11, where the source/drain portions 22 are formed on the seed features 20, respectively. In some embodiments, each of the source/drain portions 22 may include silicon germanium, silicon phosphide, or silicon arsenic. In some embodiments, the source/drain portions 22 may be formed by a suitable epitaxial growth process, for example, but not limited to, the SEG process. Other suitable processes for forming the source/drain portions 22 are within the contemplated scope of the present disclosure.

By forming the seed features 20 which have an increased density (for example, but not limited to, in a range from about 2.2 g/cm³ to about 2.3 g/cm³), and which are formed in steps S08 to S10, crystallinity of the bottom part of each of the source/drain portions 22 can be increased, and defects (e.g., voids) formed therein can be alleviated or eliminated, which is conducive to improving the device performance (e.g., a direct current (DC) performance) of the semiconductor device 200A (see FIG. 15). In addition, each of the insulators 19 can efficiently isolate a corresponding one of the seed features 20 (surrounded by the side portion 192 of the each of the insulators 19) from other components, which is conducive to reducing a leakage current between corresponding two adjacent ones of the source/drain portions 22, and to decreasing a capacitance between a corresponding one of the source/drain portions 22 and a corresponding one of a plurality of metal gates (which will be described hereinafter).

In some embodiments, the density of the source/drain portions 22 is greater than or the same as that of the first layers 18. In some embodiments, the density of the first layers 18 is greater than that of the seed features 20. In some embodiments, compared with the first layers 18 and the source/drain portions 22, a crystallinity of the seed features 20 is lower. In some embodiments, the doping concentration of the source/drain portions 22 is greater than that of the seed features 20.

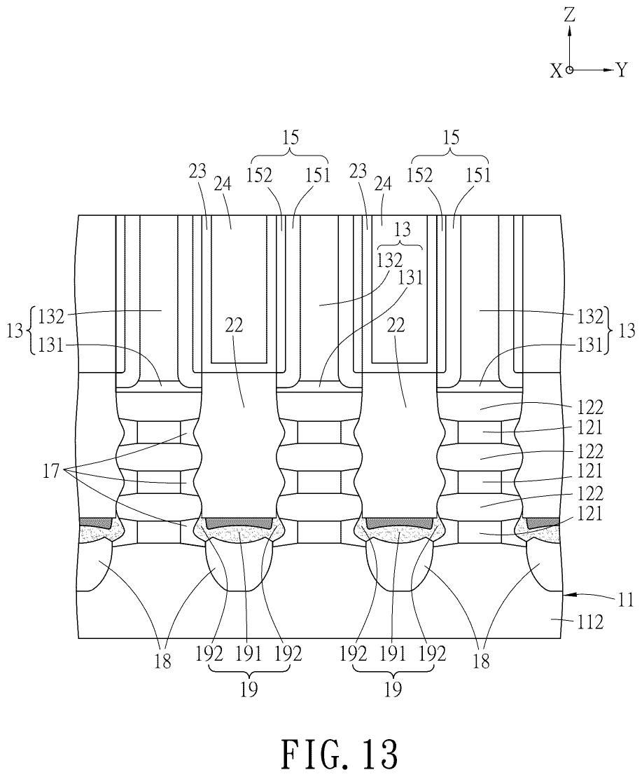

Referring to FIG. 1B and the example illustrated in FIG. 13, the method 100A then proceeds to step S12, where a plurality of contact etch stop portions 23 and a plurality of inter-layer dielectric (ILD) portions 24 are respectively formed on the source/drain portions 22. Step S12 includes sub-steps (i) to (iii).

In sub-step (i), a contact etch stop layer (not shown) for forming the contact etch stop portions 23 is conformally formed on the structure shown in FIG. 12. In some embodiments, the contact etch stop layer may include, for example, but not limited to, silicon nitride, carbon-doped silicon nitride, or a combination thereof. Other suitable materials for forming the contact etch stop layer are within the contemplated scope of the present disclosure. In some embodiments, the contact etch stop layer may be formed by a suitable deposition process, for example, but not limited to, CVD. Other suitable deposition processes for forming the contact etch stop layer are within the contemplated scope of the present disclosure.

In sub-step (ii), a dielectric material layer (not shown) for forming the ILD portions 24 is formed on the structure obtained after sub-step (i). In some embodiments, the dielectric material layer may include, for example, but not limited to, silicon oxide, silicon nitride, silicon oxynitride, other low-k dielectric materials, or combinations thereof. Other suitable materials for forming the dielectric material layer are within the contemplated scope of the present disclosure. In some embodiments, the dielectric material layer may be formed by a suitable deposition process, for example, but not limited to, CVD. Other suitable processes for forming the dielectric material layer are within the contemplated scope of the present disclosure.

In sub-step (iii), an excess portion of the dielectric material layer, an excess portion of the contact etch stop layer, the mask portions 142, the mask portions 141, and portions of the gate spacers 15 are removed by a suitable planarization process until an upper surface of each of the dummy gate electrodes 132 is exposed, thereby obtaining the contact etch stop portions 23 (i.e., remaining portions of the contact etch stop layer) and the ILD portions 24 (i.e., remaining portions of the dielectric material layer). In some embodiments, the planarization process may be, for example, but not limited to, CMP or other suitable planarization processes. In some embodiments, in this sub-step, a portion of the each of the dummy gate electrodes 132 may be removed.

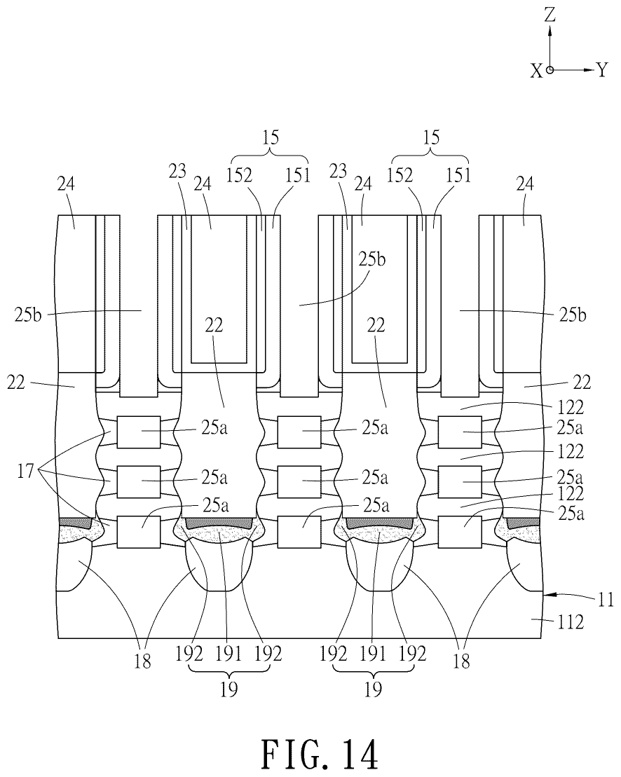

Referring to FIG. 1B and the example illustrated in FIG. 14, the method 100A then proceeds to step S13, where the sacrificial features 121 and the dummy poly gates 13 are removed, so as to form a plurality of cavities 25a, 25b. Step S13 may be performed by two or more etching processes. In some embodiments, the etching process for removing the dummy poly gates 13 may be, a wet etching process, a dry etching process, or a combination thereof. In some embodiments, the etching process for removing the sacrificial features 121 may be an isotropic dry etching process, an isotropic wet etching process, or a combination thereof. Other suitable etching processes for removing the sacrificial features 121 and the dummy poly gates 13 are within the contemplated scope of the present disclosure. The cavities 25a are defined by the inner spacers 17 and the channel features 122, and the cavities 25b are defined by the gate spacers 15 and uppermost ones of the channel features 122. In some embodiments, in this step, each of the channel features 122 may be slightly etched.

Referring to FIG. 1B and the example illustrated in FIG. 15, the method 100A then proceeds to step S14, where a plurality of interfacial features 26, a plurality of gate dielectrics 27, a plurality of gate electrodes 28, and a plurality of conductive features 29 are formed. Step S14 includes sub-steps (i) to (v).

In sub-step (i), the interfacial features 26 are formed on etched portions of the channel features 122 of the structure shown in FIG. 14, respectively. In some embodiments, the interfacial features 26 may include, for example, but not limited to, silicon oxide. Other suitable materials for forming the interfacial features 26 are within the contemplated scope of the present disclosure. In some embodiments, the interfacial features 26 may be formed by a suitable process, for example, but not limited to, a wet chemical process, ALD, or thermal oxidation. Other suitable processes for forming the interfacial features 26 are within the contemplated scope of the present disclosure. Each of the interfacial features 26 surrounds a corresponding one of the channel features 122 and is covered by a corresponding one of the gate dielectrics 27.

In sub-step (ii), a gate dielectric layer (not shown) for forming the gate dielectrics 27 is formed in the cavities 25a, 25b (see FIG. 14). In some embodiments, the gate dielectric layer may include, for example, but not limited to, silicon oxide, silicon nitride, silicon oxynitride, a suitable high-k material (e.g., hafnium oxide, zirconium oxide, zirconium aluminum oxide, hafnium aluminum oxide, hafnium silicon oxide, aluminum oxide, etc.), or combinations thereof. In some embodiments, the gate dielectric layer may be formed by a suitable deposition process, for example, but not limited to, CVD or ALD. Other suitable processes for forming the gate dielectric layer are within the contemplated scope of the present disclosure.

In sub-step (iii), a gate electrode layer (not shown) for forming the gate electrodes 28 is formed to fill the cavities 25a, 25b. In some embodiments, the gate electrode layer may include, for example, but not limited to, aluminum, copper, tungsten, cobalt, ruthenium, titanium, tantalum, molybdenum, nickel, platinum, titanium nitride, tantalum nitride, or combinations thereof. Other suitable materials for forming the gate electrode layer are within the contemplated scope of the present disclosure. In some embodiments, the gate electrode layer may be formed by a suitable deposition process, for example, but not limited to, CVD. Other suitable deposition processes for forming the gate electrode layer are within the contemplated scope of the present disclosure.

In sub-step (iv), a planarization process (e.g., CMP or other suitable planarization processes) is performed to remove an excess portion of the gate dielectric layer, an excess portion of the gate electrode layer, upper parts of the gate spacers 15, upper parts of the contact etch stop portions 23, and upper parts of the ILD portions 24, thereby obtaining the gate dielectrics 27 and the gate electrodes 28. In some embodiments, each of the gate dielectrics 27 and a corresponding one of the gate electrodes 28 may be collectively referred to as a metal gate (i.e., the metal gates are formed in this sub-step), which is configured to surround corresponding ones of the channel features 122.

In sub-step (v), the conductive features 29 are sequentially formed on corresponding ones of the source/drain portions 22. In some embodiments, each of the conductive features 29 may include, for example, but not limited to, aluminum, copper, tungsten, cobalt, ruthenium, titanium, tantalum, molybdenum, nickel, platinum, or combinations thereof. Other suitable materials for forming the conductive features 29 are within the contemplated scope of the present disclosure. In some embodiments, the conductive features 29 may be formed by conducting a photolithography process to form a plurality of through holes (not shown) which respectively penetrate corresponding ones of the ILD portions 24 and the contact etch stop portions 23, followed by sequentially depositing a conductive material layer for forming the conductive features 29 to fill the through holes and conducting a planarization process (for example, but not limited to, CMP or other suitable planarization processes) to remove an excess portion of the conductive material layer, so as to obtain the conductive features 29. During the planarization process, the gate spacers 15, the contact etch stop portions 23, the ILD portions 24, the gate dielectrics 27, and the gate electrodes 28 may be partially removed.

In some embodiments, after sub-step (iv) of step S14 and before sub-step (v) of step S14, a plurality of silicide features (not shown) may be formed. Each of the silicide features is formed between a corresponding one of the source/drain portions 22 and a corresponding one of the conductive features 29. In some embodiments, each of the silicide features may include, for example, but not limited to, titanium silicide. Other suitable materials for forming the silicide features are within the contemplated scope of the present disclosure.

After step S14, the semiconductor device 200A is obtained. In some embodiments, the semiconductor device 200A is a p-type metal-oxide-semiconductor FET (PMOSFET). In some alternative embodiments, the semiconductor device 200A is an n-type metal-oxide-semiconductor FET (NMOSFET).

In a semiconductor device of this disclosure, by having a seed feature which is disposed between an insulator and a source/drain portion and which has a density ranging from about 2.2 g/cm³ to about 2.3 g/cm³, crystallinity of a bottom part of the source/drain portion may be increased, and defects (e.g., voids) formed in the bottom part of the source/drain portion may be reduced, which is conducive to improving quality of the source/drain portion, and to further enhancing device performance (e.g., a direct current (DC) performance) of the semiconductor device.

In accordance with some embodiments of the present disclosure, a method for manufacturing a semiconductor device includes: forming a stack structure on a substrate, the stack structure including a plurality of sacrificial layer portions and a plurality of channel layer portions which are alternately stacked; forming a trench that penetrates the stack structure and that terminates at an upper surface of the substrate; forming an insulator layer to cover the substrate and the stack structure, the insulator layer including an upper portion disposed over an upper surface of the stack structure, a lower portion disposed over the substrate and in the trench, and an interconnecting portion interconnecting the upper portion and the lower portion and laterally covering the stack structure; forming a seeding layer on the insulator layer, the seeding layer including an upper portion disposed on the upper portion of the insulator layer, a lower portion disposed on the lower portion of the insulator layer, and an interconnecting portion interconnecting the upper portion and the lower portion of the seeding layer and disposed on the interconnecting portion of the insulator layer; forming a protecting layer on the seeding layer; removing the protecting layer, the upper portion and the interconnecting portion of the seeding layer, and the upper portion and the interconnecting portion of the insulator layer; and forming a source/drain portion on the lower portion of the insulator layer and the lower portion of the seeding layer.

In accordance with some embodiments of the present disclosure, each of the insulator layer and the protecting layer includes silicon nitride, silicon oxide, silicon oxynitride, or combinations thereof.

In accordance with some embodiments of the present disclosure, the seeding layer includes amorphous silicon, silicon phosphide, silicon boron, or combinations thereof.

In accordance with some embodiments of the present disclosure, a thickness of each of the upper portion and the interconnecting portion of the insulator layer is smaller than a thickness of the lower portion of the insulator layer.

In accordance with some embodiments of the present disclosure, a thickness of each of the upper portion and the interconnecting portion of the seeding layer is smaller than a thickness of the lower portion of the seeding layer.

In accordance with some embodiments of the present disclosure, the protecting layer, the upper portion and the interconnecting portion of the seeding layer, and the upper portion and the interconnecting portion of the insulator layer are removed by a dry etching process, a wet etching process, or a combination thereof.

In accordance with some embodiments of the present disclosure, a method for manufacturing a semiconductor device includes: forming two stack portions on a substrate, the two stack portions being spaced apart from each other and each of the two stack portions including a plurality of sacrificial features and a plurality of channel features which are alternately stacked; forming an insulator layer to cover the substrate and the two stack portions, the insulator layer including an upper portion disposed over an upper surface of each of the two stack portions, a lower portion disposed on the substrate and between the two stack portions, and an interconnecting portion interconnecting the upper portion and the lower portion and laterally covering each of the two stack portions; forming a seeding layer on the insulator layer, the seeding layer including an upper portion disposed on the upper portion of the insulator layer, a lower portion disposed on the lower portion of the insulator layer, and an interconnecting portion interconnecting the upper portion and the lower portion of the seeding layer and disposed on the interconnecting portion of the insulator layer; forming a protecting layer on the seeding layer; removing the protecting layer, the upper portion and the interconnecting portion of the seeding layer, and the upper portion and the interconnecting portion of the insulator layer; and forming a source/drain portion on the lower portion of the insulator layer and the lower portion of the seeding layer.

In accordance with some embodiments of the present disclosure, the seeding layer is formed by plasma-enhanced chemical vapor deposition.

In accordance with some embodiments of the present disclosure, the plasma-enhanced chemical vapor deposition is conducted using two plasma generators simultaneously. Each of the two plasma generators is a radio frequency plasma generator or a direct current plasma generator.

In accordance with some embodiments of the present disclosure, when each of the two plasma generators is the radio frequency plasma generator, one of the two plasma generators is used for conducting the plasma-enhanced chemical vapor deposition at a low frequency ranging from about 350 KHz to about 2 MHz, and the other one of the two plasma generators is used for conducting the plasma-enhanced chemical vapor deposition at a high frequency ranging from about 13 MHz to about 27 MHz.

In accordance with some embodiments of the present disclosure, the one of the two plasma generators is used for conducting the plasma-enhanced chemical vapor deposition at a power of greater than about 0 watt (W) and up to about 50 W.

In accordance with some embodiments of the present disclosure, the other one of the two plasma generators is used for conducting the plasma-enhanced chemical vapor deposition at a power ranging from about 60 W to about 300 W.

In accordance with some embodiments of the present disclosure, the two plasma generators are the direct current plasma generators, and a power of each of the direct current plasma generators is lower than about 100 W.

In accordance with some embodiments of the present disclosure, one of the two plasma generators is the direct current plasma generator that is used for conducting the plasma-enhanced chemical vapor deposition at a power lower than about 100 W, and the other one of the two plasma generators is the radio frequency plasma generator that is used for conducting the plasma-enhanced chemical vapor deposition at a power ranging from about 60 W to about 300 W and at a frequency ranging from about 13 MHz to about 27 MHz.

In accordance with some embodiments of the present disclosure, the plasma-enhanced chemical vapor deposition is conducted at a pressure ranging from about 0.4 torr (T) to about 3 T.

In accordance with some embodiments of the present disclosure, a semiconductor device includes a substrate, a plurality of first channel features, a plurality of second channel features, a first metal gate, a second metal gate, an insulator, a seed feature, and a source/drain portion. The plurality of first channel features and the plurality of second channel features are disposed on the substrate. The first metal gate is disposed to surround the plurality of first channel features. The second metal gate is disposed to surround the plurality of second channel features. The insulator is disposed between the plurality of first channel features and the plurality of second channel features, and includes a main portion and a side portion extending upwardly from a periphery of the main portion. The seed feature is disposed on the insulator, and is surrounded by the side portion of the insulator. The source/drain portion is disposed on the seed feature opposite to the main portion of the insulator.

In accordance with some embodiments of the present disclosure, the insulator includes silicon nitride, silicon oxide, silicon oxynitride, or combinations thereof.

In accordance with some embodiments of the present disclosure, the seed feature includes amorphous silicon, silicon phosphide, silicon boron, or combinations thereof.

In accordance with some embodiments of the present disclosure, the seed feature has a density ranging from about 2.2 g/cm³ to about 2.3 g/cm³.

In accordance with some embodiments of the present disclosure, a total thickness of the main portion of the insulator and the seed feature ranges from about 3 nm to about 6 nm.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a stack structure on a substrate, the stack structure including a plurality of sacrificial layer portions and a plurality of channel layer portions which are alternately stacked,
forming a trench that penetrates the stack structure and that terminates at an upper surface of the substrate;
forming an insulator layer to cover the substrate and the stack structure, the insulator layer including an upper portion disposed over an upper surface of the stack structure, a lower portion disposed over the substrate and in the trench, and an interconnecting portion interconnecting the upper portion and the lower portion and laterally covering the stack structure;
forming a seeding layer on the insulator layer, the seeding layer including an upper portion disposed on the upper portion of the insulator layer, a lower portion disposed on the lower portion of the insulator layer, and an interconnecting portion interconnecting the upper portion and the lower portion of the seeding layer and disposed on the interconnecting portion of the insulator layer;
forming a protecting layer on the seeding layer;
removing the protecting layer, the upper portion and the interconnecting portion of the seeding layer, and the upper portion and the interconnecting portion of the insulator layer; and
forming a source/drain portion on the lower portion of the insulator layer and the lower portion of the seeding layer.

2. The method as claimed in claim 1, wherein each of the insulator layer and the protecting layer includes silicon nitride, silicon oxide, silicon oxynitride, or combinations thereof.

3. The method as claimed in claim 1, wherein the seeding layer includes amorphous silicon, silicon phosphide, silicon boron, or combinations thereof.

4. The method as claimed in claim 1, wherein a thickness of each of the upper portion and the interconnecting portion of the insulator layer is smaller than a thickness of the lower portion of the insulator layer.

5. The method as claimed in claim 1, wherein a thickness of each of the upper portion and the interconnecting portion of the seeding layer is smaller than a thickness of the lower portion of the seeding layer.

6. The method as claimed in claim 1, wherein the protecting layer, the upper portion and the interconnecting portion of the seeding layer, and the upper portion and the interconnecting portion of the insulator layer are removed by a dry etching process, a wet etching process, or a combination thereof.

7. A method for manufacturing a semiconductor device, comprising:
forming two stack portions on a substrate, the two stack portions being spaced apart from each other and each of the two stack portions including a plurality of sacrificial features and a plurality of channel features which are alternately stacked;
forming an insulator layer to cover the substrate and the two stack portions, the insulator layer including an upper portion disposed over an upper surface of each of the two stack portions, a lower portion disposed on the substrate and between the two stack portions, and an interconnecting portion interconnecting the upper portion and the lower portion and laterally covering each of the two stack portions;
forming a seeding layer on the insulator layer, the seeding layer including an upper portion disposed on the upper portion of the insulator layer, a lower portion disposed on the lower portion of the insulator layer, and an interconnecting portion interconnecting the upper portion and the lower portion of the seeding layer and disposed on the interconnecting portion of the insulator layer;
forming a protecting layer on the seeding layer;
removing the protecting layer, the upper portion and the interconnecting portion of the seeding layer, and the upper portion and the interconnecting portion of the insulator layer; and
forming a source/drain portion on the lower portion of the insulator layer and the lower portion of the seeding layer.

8. The method as claimed in claim 7, wherein the seeding layer is formed by plasma-enhanced chemical vapor deposition.

9. The method as claimed in claim 8, wherein the plasma-enhanced chemical vapor deposition is conducted using two plasma generators simultaneously, each of the two plasma generators being a radio frequency plasma generator or a direct current plasma generator.

10. The method as claimed in claim 9, wherein when each of the two plasma generators is the radio frequency plasma generator, one of the two plasma generators is used for conducting the plasma-enhanced chemical vapor deposition at a low frequency ranging from 350 KHz to 2 MHz, and the other one of the two plasma generators is used for conducting the plasma-enhanced chemical vapor deposition at a high frequency ranging from 13 MHz to 27 MHz.

11. The method as claimed in claim 10, wherein the one of the two plasma generators is used for conducting the plasma-enhanced chemical vapor deposition at a power of greater than 0 watt (W) and up to 50 W.

12. The method as claimed in claim 10, wherein the other one of the two plasma generators is used for conducting the plasma-enhanced chemical vapor deposition at a power ranging from 60 W to 300 W.

13. The method as claimed in claim 10, wherein the two plasma generators are the direct current plasma generators, and a power of each of the direct current plasma generators is lower than 100 W.

14. The method as claimed in claim 9, wherein one of the two plasma generators is the direct current plasma generator that is used for conducting the plasma-enhanced chemical vapor deposition at a power lower than 100 W, and the other one of the two plasma generators is the radio frequency plasma generator that is used for conducting the plasma-enhanced chemical vapor deposition at a power ranging from 60 W to 300 W and at a frequency ranging from 13 MHz to 27 MHz.

15. The method as claimed in claim 8, wherein the plasma-enhanced chemical vapor deposition is conducted at a pressure ranging from 0.4 torr (T) to 3 T.

16. A semiconductor device, comprising:
a substrate;
a plurality of first channel features and a plurality of second channel features which are disposed on the substrate;
a first metal gate disposed to surround the plurality of first channel features;
a second metal gate disposed to surround the plurality of second channel features;
an insulator disposed between the plurality of first channel features and the plurality of second channel features, and including a main portion and a side portion extending upwardly from a periphery of the main portion;
a seed feature disposed on the insulator, and surrounded by the side portion of the insulator;
and a source/drain portion disposed on the seed feature opposite to the main portion of the insulator.

17. The semiconductor device as claimed in claim 16, wherein the insulator includes silicon nitride, silicon oxide, silicon oxynitride, or combinations thereof.

18. The semiconductor device as claimed in claim 16, wherein the seed feature includes amorphous silicon, silicon phosphide, silicon boron, or combinations thereof.

19. The semiconductor device as claimed in claim 16, wherein the seed feature has a density ranging from 2.2 g/cm³ to 2.3 g/cm³.

20. The semiconductor device as claimed in claim 16, wherein a total thickness of the main portion of the insulator and the seed feature ranges from 3 nm to 6 nm.
